(19) United States
(12) Patent Application Publication
(10) Pub. No.: US 2019/0094581 A1
(43) Pub. Date: Mar. 28, 2019

(54) LIQUID CRYSTAL DISPLAY AND MANUFACTURING METHOD THEREOF

(71) Applicant: CHUNGHWA PICTURE TUBES, LTD., Taoyuan City (TW)

(72) Inventors: Wen-Cheng LU, Taipei City (TW); Yen-Yu HUANG, Taoyuan City (TW); Che-Cheng KUO, Taoyuan City (TW)

(21) Appl. No.: 15/826,724

(22) Filed: Nov. 30, 2017

(30) Foreign Application Priority Data
Sep. 25, 2017 (CN) 201710872947.5

(51) Int. Cl. G02F 1/1339; G02F 1/1333; G02F 1/1335; H01L 27/12

(52) U.S. Cl. CPC G02F 1/1339; G02F 1/133305; G02F 1/133516; H01L 27/1218; H01L 27/1262; G02F 1/1368; G02F 2203/055; G02F 2203/01; G02F 2001/13398; G02F 2202/28; G02F 2201/501

(57) ABSTRACT

The present disclosure discloses a liquid crystal display and a manufacturing method thereof. The liquid crystal display includes a first flexible substrate, a display structure, a sealant, and a second flexible substrate. The display structure is positioned on the first flexible substrate. The sealant surrounds a side of the display structure. The second flexible substrate is positioned on the sealant and the display structure. One of the first flexible substrate and the second flexible substrate includes a first flexible material layer and a second flexible material layer. The second flexible material layer is between the first flexible material layer and the display structure and has a portion surrounding a side of the first flexible material layer and overlapping the sealant. An ultraviolet light transmission of the second flexible material layer is higher than an ultraviolet light transmission of the first flexible material layer.

### CROSS-REFERENCE TO RELATED APPLICATION

This application claims priority to China Application Serial Number 201710872947.5, filed Sep. 25, 2017, the disclosures of which are incorporated herein by reference in their entireties.

### BACKGROUND

### Field of Invention

The present invention relates to display technology. More particularly, the present invention relates to a liquid crystal display (LCD).

### Description of Related Art

Recently, with the advance of the display technique, the widely used flexible display known for its lightness, flexibility, crashworthiness and so on has been developed.

Generally speaking, the first step of manufacturing a flexible display is to fix a flexible substrate onto a carrier substrate and then fabricate display elements on the flexible substrate. After the display elements are fabricated, and the flexible display is formed, the carrier substrate is removed. However, during the process of separating the flexible substrate from the carrier substrate, the ultraviolet light used in this process might damage the display elements in the flexible display. On the other hand, fabrications of some flexible displays involve a step of curing a sealant by ultraviolet light; nevertheless, since the ultraviolet light would penetrate the flexible substrate and then irradiate the sealant, the material of the flexible substrate would affect the ultraviolet light cure performance, such that the sealant in some flexible displays may have problems of incomplete cure.

In view of the foregoing, a flexible display and a manufacturing method thereof without the problems mentioned above are required now.

### SUMMARY

The target of the present disclosure is to provide a liquid crystal display and a manufacturing method thereof to form the liquid crystal display with good quality and good mechanical strength.

One embodiment of the present disclosure provides a liquid crystal display which includes a first flexible substrate, a display structure, a sealant, and a second flexible substrate. The display structure is positioned on the first flexible substrate and includes an active element array layer, a liquid crystal layer, and a color filter layer. The liquid crystal layer is positioned on the active element array layer. The color filter layer is positioned on the liquid crystal layer. The sealant surrounds a side of the display structure. The second flexible substrate is positioned on the sealant and the display structure. One of the first flexible substrate and the second flexible substrate includes a first flexible material layer and a second flexible material layer. The second flexible material layer is between the first flexible material layer and the display structure and has a portion surrounding a side of the first flexible material layer and overlapping the sealant. An ultraviolet light transmission of the second flexible material layer is higher than an ultraviolet light transmission of the first flexible material layer.

In one or more embodiments of the present disclosure, the ultraviolet light transmission of the second flexible material layer is greater than 50% but less than 100%.

In one or more embodiments of the present disclosure, a material of the first flexible material layer and a material of the second flexible material layer are independently polyimide (PI), polyethylene terephthalate (PET), polyethylene naphthalate (PEN), polycarbonate (PC), polyethersulfone (PES), or a combination thereof.

In one or more embodiments of the present disclosure, the side of the first flexible material layer substantially aligns with the side of the display structure.

One embodiment of the present disclosure provides a manufacturing method of a liquid crystal display. The manufacturing method includes the following operations. A color filter substrate is formed by forming a first flexible material layer on a carrier substrate which includes a central region and a surrounding region surrounding the central region; patterning the first flexible material layer to expose the surrounding region of the carrier substrate; forming a second flexible material layer on the first flexible material layer and the surrounding region of the carrier substrate, wherein an ultraviolet light transmission of the second flexible material layer is higher than an ultraviolet light transmission of the first flexible material layer; and forming a color filter layer on the second flexible material layer to form the color filter substrate. A liquid crystal layer is formed between the color filter substrate and an active element array substrate, and the color filter substrate is adhered to the active element array substrate by a sealant, wherein the sealant overlaps the surrounding region of the carrier substrate.

In one or more embodiments of the present disclosure, the operation of adhering the color filter substrate to the active element array substrate by the sealant includes curing the sealant by an ultraviolet light penetrating through the second flexible material layer between the surrounding region of the carrier substrate and the sealant.

In one or more embodiments of the present disclosure, the manufacturing method of the liquid crystal display further includes performing a laser lift-off to remove the carrier substrate.

One embodiment of the present disclosure provides a manufacturing method of a liquid crystal display. The manufacturing method includes the following operations. An active element array substrate is formed by forming a first flexible material layer on a carrier substrate which includes a central region and a surrounding region surrounding the central region; patterning the first flexible material layer to expose the surrounding region of the carrier substrate; forming a second flexible material layer on the first flexible material layer and the surrounding region of the carrier substrate, wherein an ultraviolet light transmission of the second flexible material layer is higher than an ultraviolet light transmission of the first flexible material layer; and forming an active element array layer on the second flexible material layer to form the active element array substrate. A liquid crystal layer is formed between the active element array substrate and a color filter substrate, and the active element array substrate is adhered to the color filter substrate by a sealant, wherein the sealant overlaps the surrounding region of the carrier substrate.

In one or more embodiments of the present disclosure, the operation of adhering the active element array substrate to the color filter substrate by the sealant includes curing the sealant by an ultraviolet light penetrating through the second flexible material layer between the surrounding region of the carrier substrate and the sealant.

In one or more embodiments of the present disclosure, the manufacturing method of the liquid crystal display further includes performing a laser lift-off to remove the carrier substrate.

The advantages of the present disclosure include:
(1) During the process of manufacturing the above liquid crystal displays, when curing the sealant by the ultraviolet light, the structural design of the liquid crystal displays can make the sealant be cured to a greater extent.
(2) During the process of manufacturing the above liquid crystal displays, when performing the laser lift-off, the structural design of the liquid crystal displays can make the display be hardly damaged by the laser and have high acceptable lift-off rate.

### BRIEF DESCRIPTION OF THE DRAWINGS

The invention can be more fully understood by reading the following detailed description of the embodiment, with reference made to the accompanying drawings as follows:

FIG. 1 is a flow chart of a manufacturing method of a liquid crystal display, according to some embodiments of the present disclosure.

FIGS. 2-6A and 7-11 show cross section views of the liquid crystal display at different manufacturing stages respectively, according to some embodiments of the present disclosure.

FIG. 6B is a top-down view of FIG. 6A.

FIG. 12 is a flow chart of a manufacturing method of a liquid crystal display, according to some embodiments of the present disclosure.

FIGS. 13-16 show cross section views of the liquid crystal display at different manufacturing stages respectively, according to some embodiments of the present disclosure.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

Although below using a series of actions or steps described in this method disclosed, but the order of these actions or steps shown should not be construed to limit the present invention. For example, certain actions or steps may be performed in different orders and/or concurrently with other steps. Moreover, not all steps must be performed in order to achieve the depicted embodiment of the present invention. Furthermore, each operation or procedure described herein may contain several sub-steps or actions.

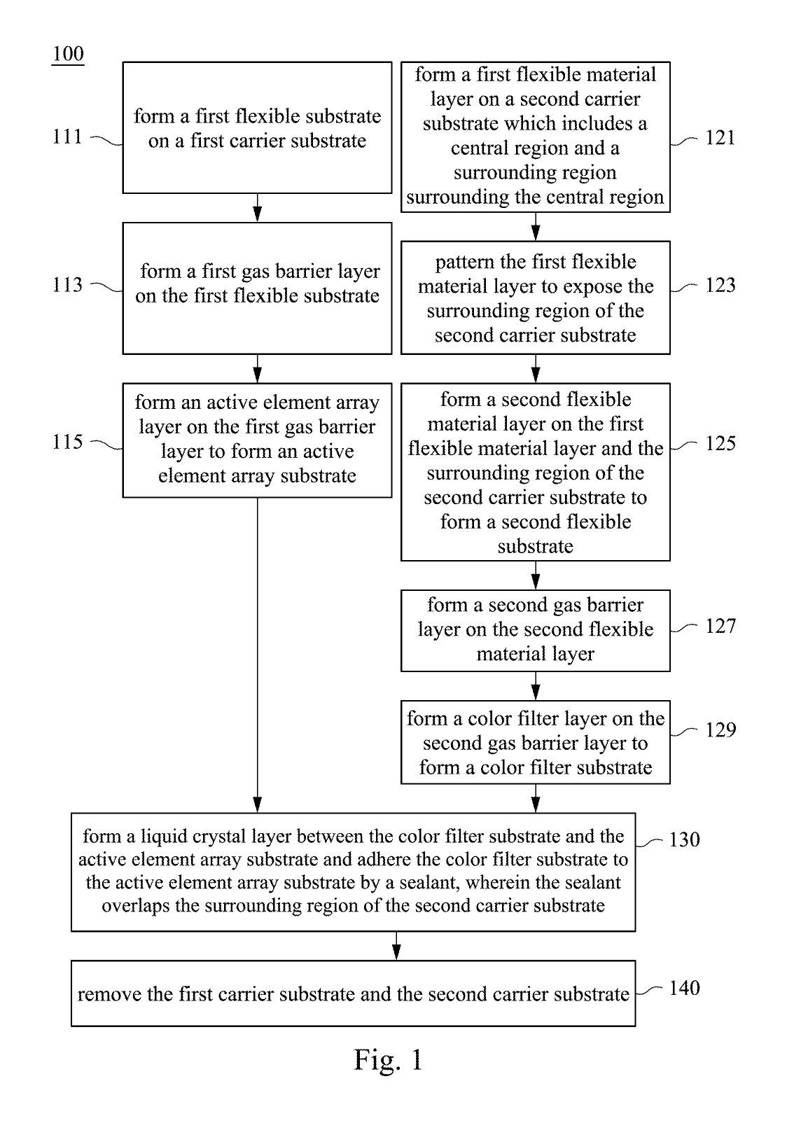

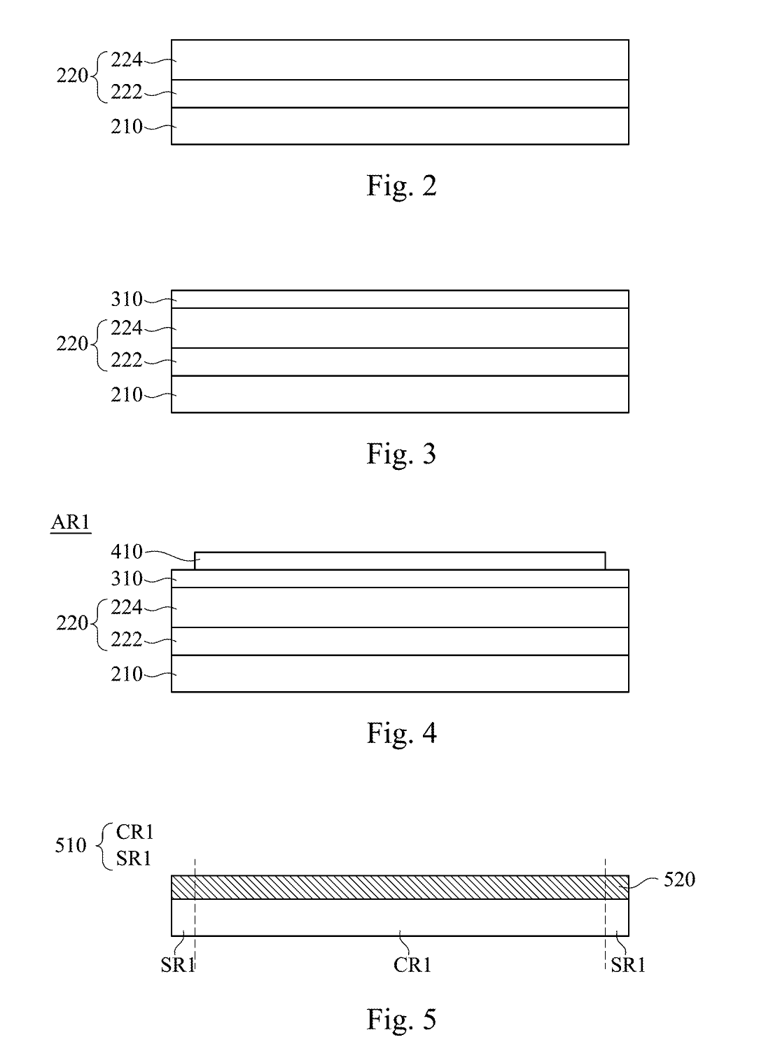

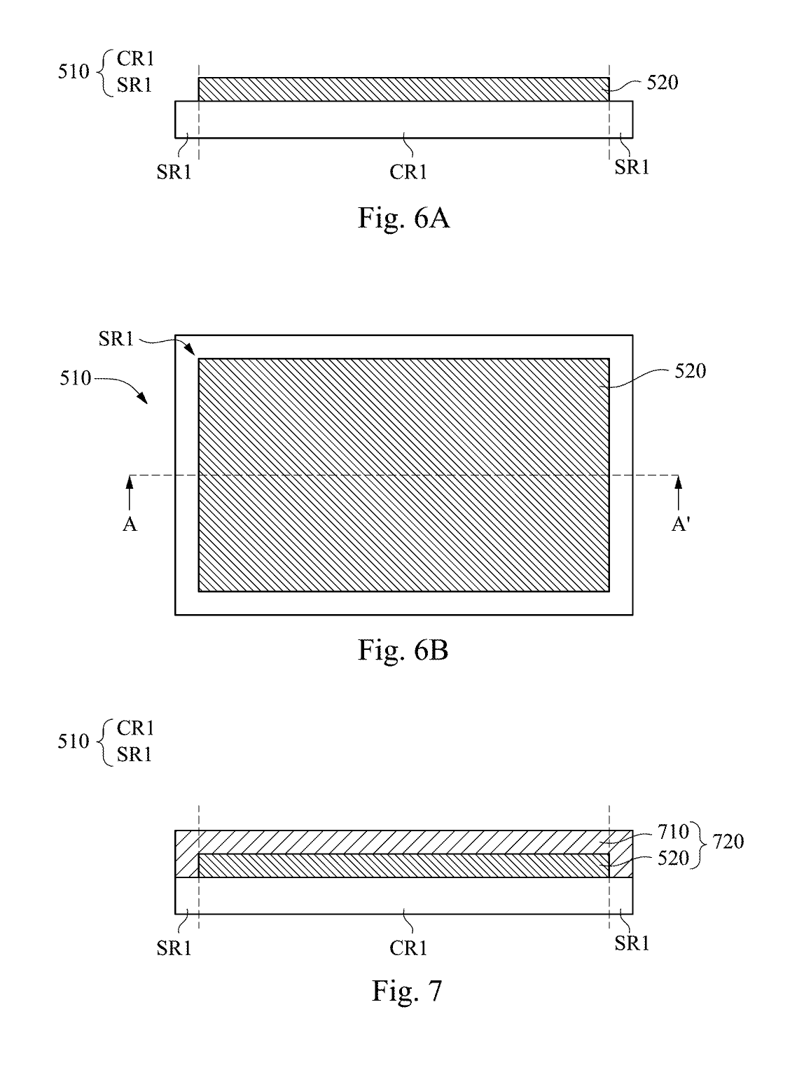

The present disclosure provides a manufacturing method of a liquid crystal display. Please refer to FIG. 1 to FIG. 11. FIG. 1 is a flow chart of a manufacturing method 100 of a liquid crystal display, according to some embodiments of the present disclosure. The manufacturing method 100 includes operations 111, 113, 115, 121, 123, 125, 127, 129, 130, and 140. FIGS. 2-6A and 7-11 show cross section views of the liquid crystal display at different manufacturing stages respectively, according to some embodiments of the present disclosure. FIG. 6B is a top-down view of FIG. 6A.

Please refer to the operations 111, 113 and 115 in FIG. 1 and FIG. 2 to FIG. 4. The present disclosure provides a manufacturing method of an active element array substrate. FIGS. 2 to 4 show cross section views of the active element array substrate at different manufacturing stages respectively.

In the operation 111, as shown in FIG. 2, a first flexible substrate 220 is formed on a first carrier substrate 210. In some embodiments, the first flexible substrate 220 includes a flexible material layer 222 and a flexible material layer 224. In some embodiments, the flexible material layer 222 is first formed on the first carrier substrate 210, and then the flexible material layer 224 is formed on the flexible material layer 222. For instance, the flexible material layer 222 and the flexible material layer 224 can be formed by coating and curing respectively. In some embodiments, the operation of forming the flexible material layer 224 can be omitted, and thus the flexible material layer 222 is the first flexible substrate 220.

In some embodiments, the first carrier substrate 210 is a glass substrate. In some embodiments, an ultraviolet light transmission of the flexible material layer 224 is higher than an ultraviolet light transmission of the flexible material layer 222. In some embodiments, the ultraviolet light transmission of the flexible material layer 222 ranges between 0% and 50%. For example, its ultraviolet light transmission is 10%, 20%, 30%, or 40%. The flexible material layer 222 has lower ultraviolet light transmission, which facilitates the following fabrication that separates the first flexible substrate 220 from the first carrier substrate 210 by laser lift-off. In some embodiments, the ultraviolet light transmission of the flexible material layer 224 is greater than 50% but less than 100%. For instance, its ultraviolet light transmission is 60%, 70%, 80%, or 90%. In some embodiments, a material of the flexible material layer 222 and a material of the flexible material layer 224 are independently polyimide, polyethylene terephthalate, polyethylene naphthalate, polycarbonate, polyethersulfone, or a combination thereof. In some embodiments, the material of the flexible material layer 222 is different from the material of the flexible material layer 224. In some embodiments, the material of the flexible material layer 222 and the material of the flexible material layer 224 are polyimide respectively. The ultraviolet light transmission of the polyimide of the flexible material layer 224 is greater than the ultraviolet light transmission of the polyimide of the flexible material layer 222.

In the operation 113, as shown in FIG. 3, a first gas barrier layer 310 is formed on the first flexible substrate 220. In some embodiments, a material of the first gas barrier layer 310 includes silicon oxide, epoxy, acrylic resin, melamine resin, or a combination thereof.

In the operation 115, as shown in FIG. 4, an active element array layer 410 is formed on the first gas barrier layer 310 to form an active element array substrate AR1. The active element array substrate AR1 includes the first carrier substrate 210, the first flexible substrate 220, the first gas barrier layer 310, and the active element array layer 410. In some embodiments, the operation 113 is omitted; therefore, the active element array layer 410 is directly formed on the flexible material layer 224. In some embodiments, the active elements (not shown) in the active element array layer 410 include amorphous silicon thin film transistor (a-Si TFT), poly-silicon TFT, micro-Si TFT, metal oxide TFT, or a combination thereof.

Please refer to the operations 121, 123, 125, 127 and 129 in FIG. 1 and FIG. 5 to FIG. 9. The present disclosure provides a manufacturing method of a color filter substrate. FIGS. 5, 6A, and 7 to 9 show cross section views of the color filter substrate at different manufacturing stages respectively.

In the operation 121, as shown in FIG. 5, a first flexible material layer 520 is formed on the second carrier substrate 510. The second carrier substrate 510 includes a central region CR1 and a surrounding region SR1 which surrounds the central region CR1. For instance, the first flexible material layer 520 can be formed by coating and curing. In some embodiments, the second carrier substrate 510 is a glass substrate.

In the operation 123, as shown in FIG. 6A, the first flexible material layer 520 is patterned to expose the surrounding region SR1 of the second carrier substrate 510. FIG. 6A is a cross section view of FIG. 6B along the line A-A′. From the top view, as shown in FIG. 6B, the surrounding region SR1 of the second carrier substrate 510 surrounds the patterned first flexible material layer 520. In some other embodiments, a portion of patterned first flexible material layer 520 covers on the surrounding region SR1 of the second carrier substrate 510 (not shown), and a portion of the surrounding region SR1 of the second carrier substrate 510 is exposed. In some embodiments, the first flexible material layer 520 is patterned by etching, such as dry etching and wet etching. For instance, the etchant is N-methyl-2-pyrrolidone (NMP) or N—N dimethlacetamide (DMAC). In some other embodiments, the first flexible material layer 520 is patterned by cutting the first flexible material layer 520 with a cutter wheel or a blade.

In some embodiments, the ultraviolet light transmission of the first flexible material layer 520 ranges between 0% and 50%. For example, its ultraviolet light transmission is 10%, 20%, 30%, or 40%. The first flexible material layer 520 has lower ultraviolet light transmission, which facilitates the following fabrication that separates the first flexible material layer 520 from the second carrier substrate 520 by laser lift-off.

In the operation 125, as shown in FIG. 7, a second flexible material layer 710 is formed on both the first flexible material layer 520 and the surrounding region SR1 of the second carrier substrate 510 to form a second flexible substrate 720. The second flexible substrate 720 includes the first flexible material layer 520 and the second flexible material layer 710. An ultraviolet light transmission of the second flexible material layer 710 is higher than an ultraviolet light transmission of the first flexible material layer 520. For example, the second flexible material layer 710 can be formed by coating and curing. In some embodiments, an ultraviolet light transmission of the second flexible material layer 710 is greater than 50% but less than 100%. For instance, its ultraviolet light transmission is 60%, 70%, 80%, or 90%.

In some embodiments, a material of the first flexible material layer 520 and a material of the second flexible material layer 710 are independently polyimide, polyethylene terephthalate, polyethylene naphthalate, polycarbonate, polyethersulfone, or a combination thereof. In some embodiments, the material of the first flexible material layer 520 is different from the material of the second flexible material layer 710. In some embodiments, the material of the first flexible material layer 520 and the material of the second flexible material layer 710 are polyimide. The ultraviolet light transmission of the polyimide of the second flexible material layer 710 is greater than the ultraviolet light transmission of the polyimide of the first flexible material layer 520.

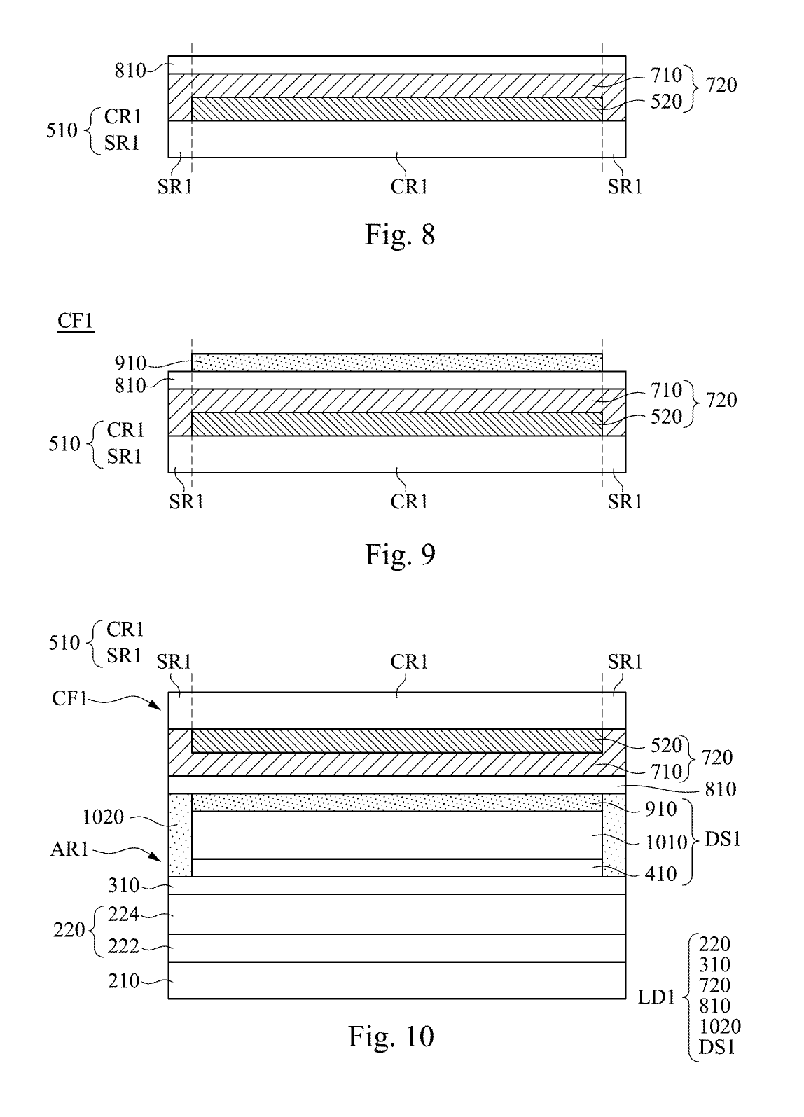

In the operation 127, as shown in FIG. 8, a second gas barrier layer 810 is formed on the second flexible material layer 710. In some embodiments, the material of the second gas barrier layer 810 includes silicon oxide, epoxy, acrylic resin, melamine resin, or a combination thereof.

In the operation 129, as shown in FIG. 9, a color filter layer 910 is formed on the second gas barrier layer 810 to form a color filter substrate CF1. The color filter substrate CF1 includes the second carrier substrate 510, the second flexible substrate 720, the second gas barrier layer 810, and the color filter layer 910. In some embodiments, the operation 127 is omitted; thus, the color filter layer 910 is directly formed on the second flexible material layer 710.

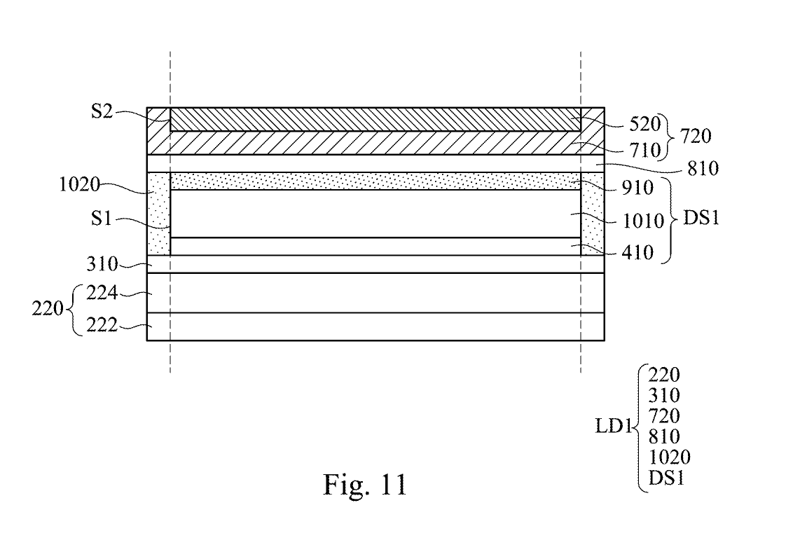

Please refer to the operations 130 and 140 in FIG. 1 and FIG. 10 to FIG. 11. The operations 130 and 140 and FIG. 10 to FIG. 11 describe a cell alignment process. The active element array substrate AR1 shown in FIG. 4 is adhered to the color filter substrate CF1 shown in FIG. 9, and a liquid crystal layer 1010 is formed between the active element array substrate AR1 and the color filter substrate CF1 to form a liquid crystal display LD1. Besides, after the cell alignment process, the fabrication of the liquid crystal display LD1 often includes operations, such as cell cracking and bonding with a circuit board. The above operations are well-known, and thus will not be described herein.

In the operation 130, as shown in FIG. 10, the liquid crystal layer 1010 is formed between the color filter substrate CF1 and the active element array substrate AR1. Furthermore, the color filter substrate CF1 is adhered to the active element array substrate AR1 by a sealant 1020. The sealant 1020 overlaps the surrounding region SR1 of the second carrier substrate 510 to form the liquid crystal display LD1 disposed between the first carrier substrate 210 and the second carrier substrate 510. In the present disclosure, the term “overlap” in its meaning includes completely overlapping and partially overlapping. In some embodiments, the liquid crystal layer 1010 is formed by using an one drop filling (ODF). The liquid crystal display LD1 includes the first flexible substrate 220, the first gas barrier layer 310, the display structure DS1, the sealant 1020, the second gas barrier layer 810 and the second flexible substrate 720. The display structure DS1 is disposed between the first gas barrier layer 310 and the second gas barrier layer 810. The display structure DS1 includes the liquid crystal layer 1010, the active element array layer 410 and the color filter layer 910. The liquid crystal layer 1010 is disposed between the active element array layer 410 and the color filter layer 910. In some embodiments, the liquid crystal display LD1 is called flexible LCD (FLCD).

In some embodiments, the operation of adhering the color filter substrate CF1 to the active element array substrate AR1 by the sealant 1020 includes curing the sealant 1020 by an ultraviolet light penetrating through the second flexible material layer 710 between the surrounding region SR1 of the second carrier substrate 510 and the sealant 1020. In some embodiments, the sealant 1020 is ultraviolet curable adhesive. The ultraviolet light enters the second carrier substrate 510, then penetrates the second flexible material layer 710 and the second gas barrier layer 810, and eventually irradiates the sealant 1020 to cure the sealant 1020. In some embodiments, the wavelength of the ultraviolet light ranges between about 10 nm and about 400 nm. It is noted that since the second flexible material layer 710 between the surrounding region SR1 of the second carrier substrate 510 and the sealant 1020 has higher ultraviolet light transmission, the sealant 1020 irradiated by the ultraviolet light can be cured to a greater extent. In other word, the curing conversion rate of the sealant 1020 can be increased. Accordingly, when the liquid crystal display LD1 is bended, the separation between the color filter substrate CF1 and the active element array substrate AR1 hardly occurs, leading to greater mechanical strength of the liquid crystal display LD1.

In the operation 140, the first carrier substrate 210 and the second carrier substrate 510 are removed. FIG. 11 shows the liquid crystal display LD1 after removing the first carrier substrate 210 and the second carrier substrate 510. In some embodiments, the first carrier substrate 210 and the second carrier substrate 510 are removed by laser lift-off. In some embodiments, the laser lift-off is performed by ultraviolet light. For example, the laser lift-off can be performed by the diode-pumped solid-state laser (DPSS laser) or the excimer laser. It is noted that since the first flexible material layer 520 has a lower ultraviolet light transmission, when the laser lift-off is performed, the second flexible substrate 720 can be easily separated from the second carrier substrate 510. Furthermore, because the first flexible material layer 520 overlaps the display structure DS1, the display structure DS1 is hardly damaged as the laser lift-off is performed.

As shown in FIG. 11, the liquid crystal display LD1 includes the first flexible substrate 220, the first gas barrier layer 310, the display structure DS1, the sealant 1020, the second gas barrier layer 810 and the second flexible substrate 720. The display structure DS1 is positioned on the first flexible substrate 220. The first gas barrier layer 310 is positioned between the first flexible substrate 220 and the display structure DS1. The display structure DS1 includes the active element array layer 410, the liquid crystal layer 1010 and the color filter layer 910. The liquid crystal layer 1010 is positioned on the active element array layer 410. The color filter layer 910 is positioned on the liquid crystal layer 1010. The sealant 1020 surrounds a side S1 of the display structure DS1. The second flexible substrate 720 is positioned on both the sealant 1020 and the display structure DS1. The second gas barrier layer 810 is positioned between the second flexible substrate 720 and the display structure DS1. The second flexible substrate 720 includes the first flexible material layer 520 and the second flexible material layer 710. The second flexible material layer 710 is between the first flexible material layer 520 and the display structure DS1 and has a portion surrounding a side S2 of the first flexible material layer 520 and overlapping the sealant 1020. The ultraviolet light transmission of the second flexible material layer 710 is higher than the ultraviolet light transmission of the first flexible material layer 520. In some embodiments, the side S2 of the first flexible material layer 520 substantially aligns with the side S1 of the display structure DS1.

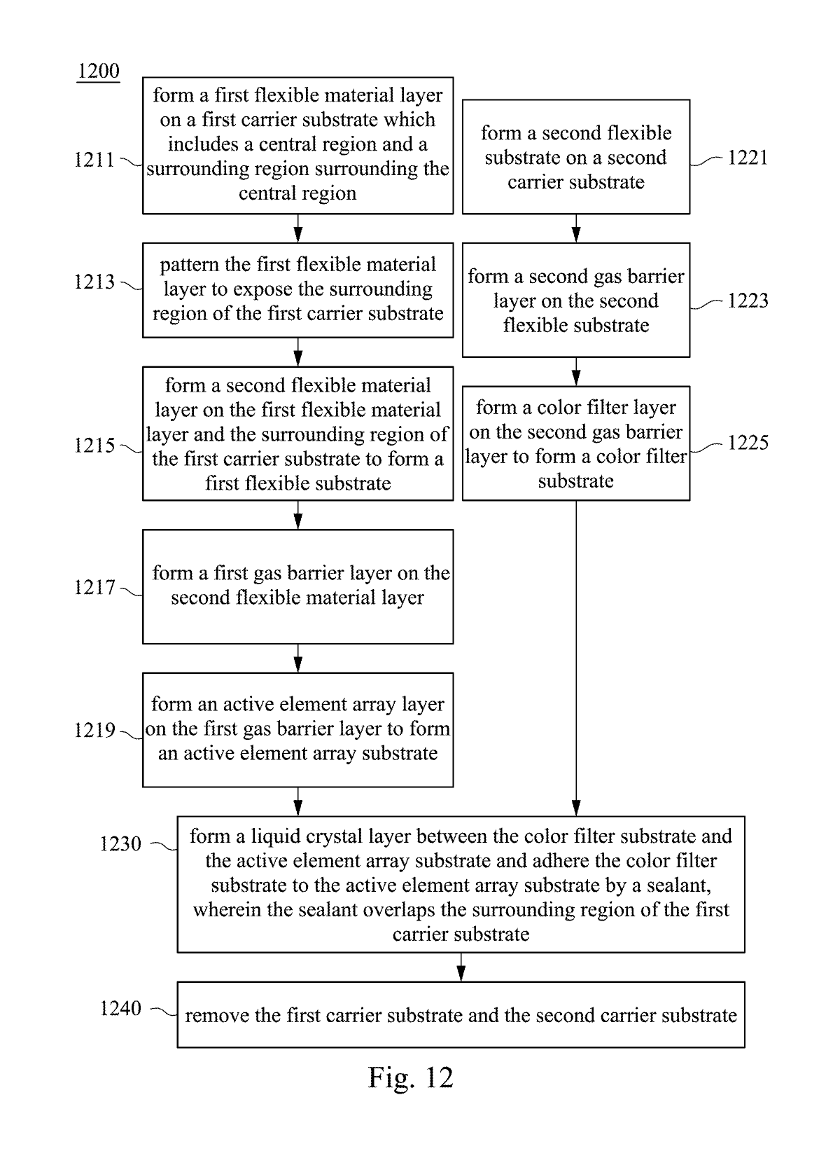

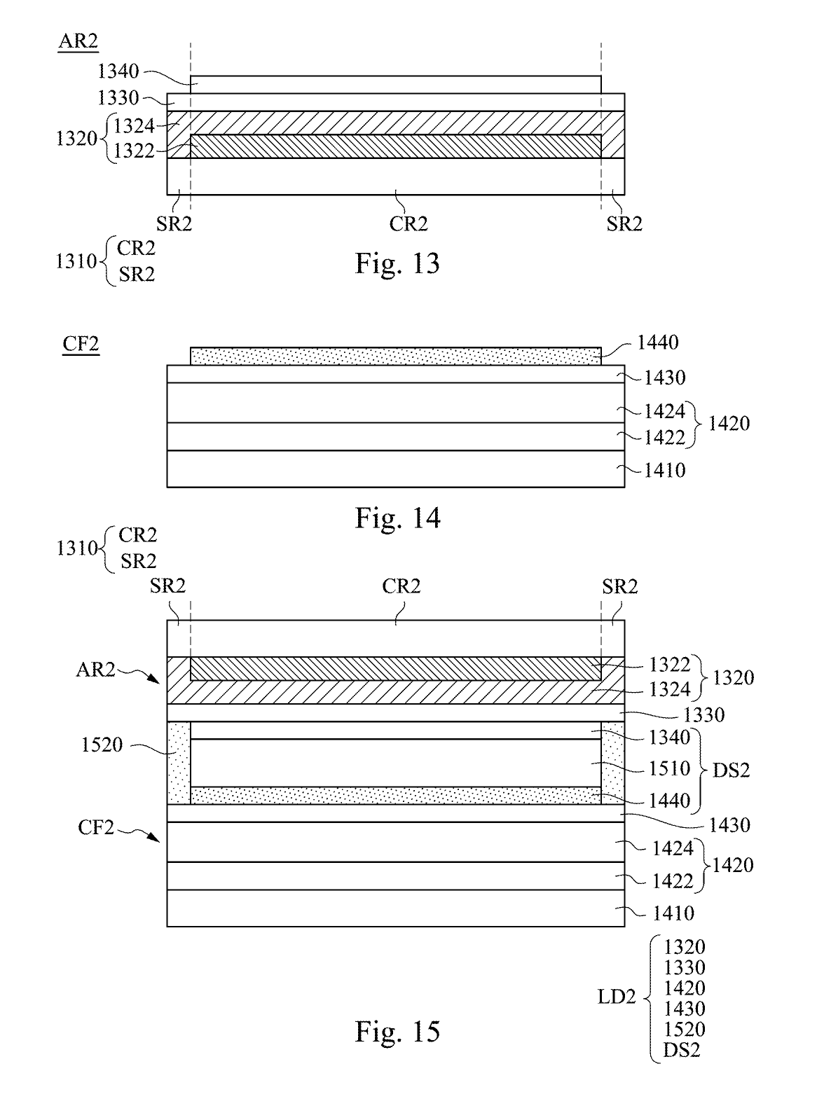

Next, the present disclosure provides another manufacturing method of a liquid crystal display. Please refer to FIG. 12 to FIG. 16. FIG. 12 is a flow chart of a manufacturing method 1200 of a liquid crystal display, according to some embodiments of the present disclosure. The manufacturing method 1200 includes operations 1211, 1213, 1215, 1217, 1219, 1221, 1223, 1225, 1230 and 1240. FIGS. 13-16 show cross section views of the liquid crystal display at different manufacturing stages respectively, according to some embodiments of the present disclosure.

Please refer to the operations 1211, 1213, 1215, 1217 and 1219 in FIG. 12 and FIG. 13. The present disclosure provides a manufacturing method of an active element array substrate.

In the operation 1211, a first flexible material layer is formed on a first carrier substrate 1310. The first carrier substrate 1310 includes a central region CR2 and a surrounding region SR2 surrounding the central region CR2. In the operation 1213, the first flexible material layer is patterned to expose the surrounding region SR2 of the first carrier substrate 1310. FIG. 13 shows a first flexible material layer 1322 after being patterned. In the operation 1215, a second flexible material layer 1324 is formed on the first flexible material layer 1322 and the surrounding region SR2 of the first carrier substrate 1310 to form a first flexible substrate 1320. The first flexible substrate 1320 includes the first flexible material layer 1322 and the second flexible material layer 1324. An ultraviolet light transmission of the second flexible material layer 1324 is higher than an ultraviolet light transmission of the first flexible material layer 1322. In some embodiments, the ultraviolet light transmission of the first flexible material layer 1322 ranges between 0% and 50%. For example, its ultraviolet light transmission is 10%, 20%, 30%, or 40%. In some embodiments, the ultraviolet light transmission of the second flexible material layer 1324 is greater than 50% but less than 100%. For instance, its ultraviolet light transmission is 60%, 70%, 80%, or 90%. In some embodiments, a material of the first flexible material layer 1322 and a material of the second flexible material layer 1324 are independently polyimide, polyethylene terephthalate, polyethylene naphthalate, polycarbonate, polyethersulfone, or a combination thereof. In the operation 1217, a first gas barrier layer 1330 is formed on the second flexible material layer 1324. Please refer to the operations 121, 123, 125 and 127 for the operations 1211, 1213, 1215 and 1217. The descriptions for the embodiments of the first carrier substrate 1310, the first flexible material layer 1322, the second flexible material layer 1324 and the first gas barrier layer 1330 could be same as or similar to the previous cases of the second carrier substrate 510, the first flexible material layer 520, the second flexible material layer 710 and the second gas barrier layer 810 respectively.

In the operation 1219, an active element array layer 1340 is formed on the first gas barrier layer 1330 to form an active element array substrate AR2. The active element array substrate AR2 includes the first carrier substrate 1310, the first flexible substrate 1320, the first gas barrier layer 1330, and the active element array layer 1340. Please refer to the operation 115 for the operation 1219. The description for the embodiments of the active element array layer 1340 is same as or similar to the previous cases of the active element array layer 410.

Please refer to the operations 1221, 1223 and 1225 in FIG. 12 and FIG. 14. The present disclosure provides a manufacturing method of a color filter substrate.

In the operation 1221, a second flexible substrate 1420 is formed on a second carrier substrate 1410. In some embodiments, the second flexible substrate 1420 includes a flexible material layer 1422 and a flexible material layer 1424. In some embodiments, the flexible material layer 1422 is first formed on the second carrier substrate 1410, and then the flexible material layer 1424 is formed on the flexible material layer 1422. In the operation 1223, a second gas barrier layer 1430 is formed on the second flexible substrate 1420. Please refer to the operations 111 and 113 for the operations 1211 and 1223. The descriptions for the embodiments of the second carrier substrate 1410, the second flexible substrate 1420 and the second gas barrier layer 1430 can be same as or similar to the previous cases of the first carrier substrate 210, the first flexible substrate 220 and the first gas barrier layer 310 respectively. In the operation 1225, the color filter layer 1440 is formed on the second gas barrier layer 1430 to form a color filter substrate CF2. The color filter substrate CF2 includes the second carrier substrate 1410, the second flexible substrate 1420, the second gas barrier layer 1430 and the color filter layer 1440. Please refer to the operation 129 for the operation 1225. The description for the embodiments of the color filter layer 1440 is same as or similar to the previous cases of the color filter layer 910.

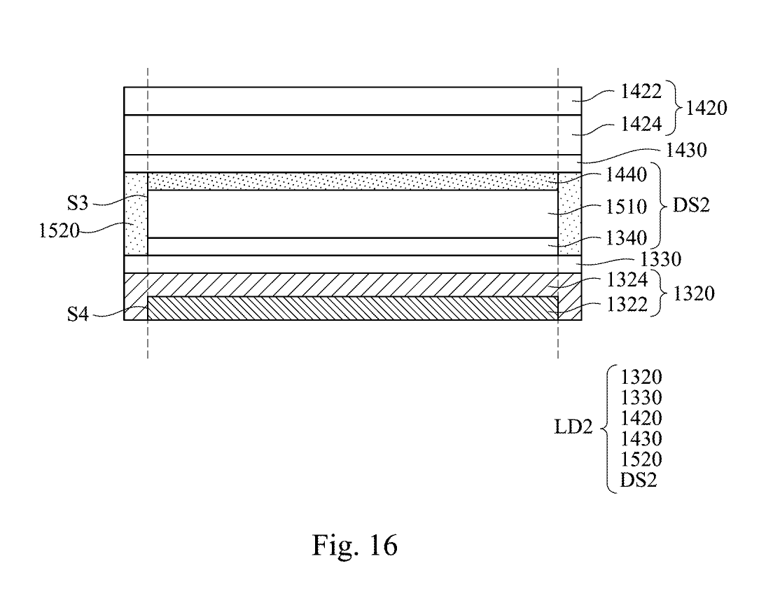

Please refer to the operations 1230 and 1240 in FIG. 12 and FIG. 15 to FIG. 16. The operations 1230 and 1240 and FIG. 15 to FIG. 16 describe a cell alignment process. The active element array substrate AR2 shown in FIG. 13 is adhered to the color filter substrate CF2 shown in FIG. 14, and a liquid crystal layer 1510 is formed between the active element array substrate AR2 and the color filter substrate CF2 to form a liquid crystal display LD2.

In the operation 1230, as shown in FIG. 15, the liquid crystal layer 1510 is formed between the color filter substrate CF2 and the active element array substrate AR2, and the color filter substrate CF2 is adhered to the active element array substrate AR2 by a sealant 1520, wherein the sealant 1520 overlaps the surrounding region SR2 of the first carrier substrate 1310. Please refer to the operation 130 for the operation 1230. The description for the embodiments of the liquid crystal display LD2 is same as or similar to the previous case of the liquid crystal display LD1.

The liquid crystal display LD2 includes the first flexible substrate 1320, the first gas barrier layer 1330, the display structure DS2, the sealant 1520, the second gas barrier layer 1430 and the second flexible substrate 1420. The display structure DS2 is disposed between the first gas barrier layer 1330 and the second gas barrier layer 1430. The display structure DS2 includes the liquid crystal layer 1510, the active element array layer 1340 and the color filter layer 1440. The liquid crystal layer 1510 is disposed between the active element array layer 1340 and the color filter layer 1440.

In some embodiments, the operation of adhering the active element array substrate AR2 to the color filter substrate CF2 by the sealant 1520 includes curing the sealant 1520 by an ultraviolet light penetrating through the second flexible material layer 1324 between the surrounding region SR2 of the first carrier substrate 1310 and the sealant 1520. In some embodiments, the sealant 1520 is ultraviolet curable adhesive.

In the operation 1240, the first carrier substrate 1310 and the second carrier substrate 1410 are removed. FIG. 16 shows the liquid crystal display LD2 after removing the first carrier substrate 1310 and the second carrier substrate 1410. In some embodiments, the first carrier substrate 1310 and the second carrier substrate 1410 are removed by performing laser lift-off. Please refer to the operation 140 for the operation 1240. The descriptions for the embodiments of removing the first carrier substrate 1310 and the second carrier substrate 1410 are same as or similar to the previous cases of removing the first carrier substrate 210 and the second carrier substrate 510. For the convenience of comparing the liquid crystal display LD2 in FIG. 16 to the liquid crystal display LD1 in FIG. 11, the liquid crystal display LD2 in FIG. 16 is the result of the liquid crystal display LD2 in FIG. 15 being flipped 180 degrees.

As shown in FIG. 16, the liquid crystal display LD2 includes the first flexible substrate 1320, the first gas barrier layer 1330, the display structure DS2, the sealant 1520, the second gas barrier layer 1430 and the second flexible substrate 1420. The display structure DS2 is positioned on the first flexible substrate 1320. The first gas barrier layer 1330 is positioned between the first flexible substrate 1320 and the display structure DS2. The display structure DS2 includes the active element array layer 1340, the liquid crystal layer 1510, and the color filter layer 1440. The liquid crystal layer 1510 is positioned on the active element array layer 1340. The color filter layer 1440 is positioned on the liquid crystal layer 1510. The sealant 1520 surrounds a side S3 of the display structure DS2. The second flexible substrate 1420 is positioned on both the sealant 1520 and the display structure DS2. The second gas barrier layer 1430 is positioned between the second flexible substrate 1420 and the display structure DS2. The first flexible substrate 1320 includes the first flexible material layer 1322 and the second flexible material layer 1324. The second flexible material layer 1324 is between the first flexible material layer 1322 and the display structure DS2 and has a portion surrounding a side S4 of the first flexible material layer 1322 and overlapping the sealant 1520. The ultraviolet light transmission of the second flexible material layer 1324 is higher than the ultraviolet light transmission of the first flexible material layer 1322. In some embodiments, the side S4 of the first flexible material layer 1322 substantially aligns with the side S3 of the display structure DS2.

Based on the above, in the different embodiments of the present disclosure, one of the first flexible substrate and the second flexible substrate in the liquid crystal display includes two flexible material layers with different ultraviolet light transmissions. The flexible material layer with the higher ultraviolet light transmission overlaps the sealant. As a result, when the sealant is cured by ultraviolet light, the sealant can be cured to a greater extent. On the other hand, since the flexible substrate includes the flexible material layer with lower ultraviolet light transmission, the flexible substrate can be easily separated from the carrier substrate when the laser lift-off is performed. Moreover, since the flexible material layer with the lower ultraviolet light transmission overlaps the display structure, the display structure is hardly damaged by the laser when the laser lift-off is performed. Accordingly, by the manufacturing methods of the liquid crystal displays of the different embodiments in the present disclosure, the liquid crystal display with good quality and good mechanical strength can be obtained.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A liquid crystal display, comprising:
a first flexible substrate;
a display structure positioned on the first flexible substrate, the display structure comprising:
an active element array layer;
a liquid crystal layer positioned on the active element array layer; and
a color filter layer positioned on the liquid crystal layer;
a sealant surrounding a side of the display structure; and
a second flexible substrate positioned on the sealant and the display structure;
wherein one of the first flexible substrate and the second flexible substrate comprises a first flexible material layer and a second flexible material layer, the second flexible material layer is between the first flexible material layer and the display structure and has a portion surrounding a side of the first flexible material layer and overlapping the sealant, and an ultraviolet light transmission of the second flexible material layer is higher than an ultraviolet light transmission of the first flexible material layer.

2. The liquid crystal display of claim 1, wherein the ultraviolet light transmission of the second flexible material layer is greater than 50% but less than 100%.

3. The liquid crystal display of claim 1, wherein a material of the first flexible material layer and a material of the second flexible material layer are independently polyimide, polyethylene terephthalate, polyethylene naphthalate, polycarbonate, polyethersulfone, or a combination thereof.

4. The liquid crystal display of claim 1, wherein the side of the first flexible material layer substantially aligns with the side of the display structure.

5. A manufacturing method of a liquid crystal display, comprising:
forming a color filter substrate, comprising:
forming a first flexible material layer on a carrier substrate which includes a central region and a surrounding region surrounding the central region;
patterning the first flexible material layer to expose the surrounding region of the carrier substrate;
forming a second flexible material layer on the first flexible material layer and the surrounding region of the carrier substrate, wherein an ultraviolet light transmission of the second flexible material layer is higher than an ultraviolet light transmission of the first flexible material layer; and
forming a color filter layer on the second flexible material layer to form the color filter substrate; and
forming a liquid crystal layer between the color filter substrate and an active element array substrate and adhering the color filter substrate to the active element array substrate by a sealant, wherein the sealant overlaps the surrounding region of the carrier substrate.

6. The manufacturing method of claim 5, wherein adhering the color filter substrate to the active element array substrate by the sealant comprises curing the sealant by an ultraviolet light penetrating through the second flexible material layer between the surrounding region of the carrier substrate and the sealant.

7. The manufacturing method of claim 5, further comprising performing a laser lift-off to remove the carrier substrate.

8. A manufacturing method of a liquid crystal display, comprising:
forming an active element array substrate, comprising:
forming a first flexible material layer on a carrier substrate which includes a central region and a surrounding region surrounding the central region;
patterning the first flexible material layer to expose the surrounding region of the carrier substrate;
forming a second flexible material layer on the first flexible material layer and the surrounding region of the carrier substrate, wherein an ultraviolet light transmission of the second flexible material layer is higher than an ultraviolet light transmission of the first flexible material layer; and
forming an active element array layer on the second flexible material layer to form the active element array substrate; and
forming a liquid crystal layer between the active element array substrate and a color filter substrate and adhering the active element array substrate to the color filter substrate by a sealant, wherein the sealant overlaps the surrounding region of the carrier substrate.

9. The manufacturing method of claim 8, wherein adhering the active element array substrate to the color filter substrate by the sealant comprises curing the sealant by an ultraviolet light penetrating through the second flexible material layer between the surrounding region of the carrier substrate and the sealant.

10. The manufacturing method of claim 8, further comprising performing a laser lift-off to remove the carrier substrate.
